(19) United States
(12) Patent Application Publication
(10) Pub. No.: US 2015/0377993 A1
(43) Pub. Date: Dec. 31, 2015

(54) Method and Device for Magnetic Field Correction for an NMR Machine

(71) Applicant: COMMISSARIAT A L'ENERGIE ATOMIQUE ET AUX ENERGIES ALTERNATIVES, Paris (FR)

(72) Inventors: Dimitri Sakellariou, Boulogne-Billancourt (FR); Cedric Hugon, Teche (FR); Guy Aubert, Poitiers (FR)

(73) Assignee: COMMISSARIAT A L'ENERGIE ATOMIQUE ET AUX ENERGIES ALTERNATIVES, Paris (FR)

(21) Appl. No.: 14/768,645

(22) PCT Filed: Feb. 18, 2014
(86) PCT No.: PCT/FR2014/050335

§ 371 Date: Aug. 18, 2015

(30) Foreign Application Priority Data
Feb. 19, 2013 (FR) 1351396

(51) Int. Cl. G01R 33/3875; G01R 33/30

(52) U.S. Cl. CPC G01R 33/3875; G01R 33/307

(57) ABSTRACT

A device for magnetic field correction in an NMR system includes a device for creating a homogeneous main magnetic field along a direction Oz in a zone of interest ZI, a device for supporting a sample with a main dimension of the sample being oriented at an angle θ₀ other than zero relative to the direction Oz, gradient coils, and radiofrequency coils. The device also includes a set of correction coils positioned around the device for supporting the sample. Each correction coil presents an axis coinciding with the direction Oz and includes winding elements made from iso-contours of a flux function that are regularly spaced apart between limits of the flux function on a cylinder.

### FIELD OF THE INVENTION

The present invention provides a method and a device for magnetic field correction, suitable for use in particular in the technique of creating spectra and images by nuclear magnetic resonance (NMR), this technique also being known as magnetic resonance imaging (MRI).

The invention also relates to a magnetic resonance imaging system using such a magnetic field correction method.

### PRIOR ART

MRI and NMR rely on using magnetic fields, including a so-called “main” magnetic field that needs to be as uniform as possible in the region under examination or zone of interest ZI. Conventionally, the term “homogeneous” is used to designate this uniform nature. This magnetic field of great homogeneity is generated by magnets, and nowadays those in the most widespread use are constituted by superconducting windings conveying electric currents for generating the field without dissipating any energy, providing they are maintained at very low temperature. Such a magnet device generally has the external appearance of a cylindrical tunnel into which the object or the patient for imaging is inserted.

Analyzing anisotropic samples, e.g. solids, by means of NMR requires the sample to be made to rotate about an axis that is oriented at an angle that is said to be “magic” (arctan(√2)≈54.7°. The sample is generally of cylindrical shape, and its length is often much longer than its diameter (by a factor of 2 to a factor of 10). This aspect ratio is also to be found when performing NMR on isotropic samples, e.g. liquids, where the sample is typically contained in a tube having a diameter of 5 millimeters (mm) and the height of the sample in the tube is usually of the order of one or more centimeters.

NMR spectroscopy, whether in the anisotropic state (solid) or in the isotropic state (liquid), requires an ambient magnetic field that is extremely uniform in three dimensions. Samples are analyzed by analyzing the NMR spectrum, which is constituted by the frequency response of the sample when it is excited by radio-frequency (RF) pulses. This response depends directly on the local value of the magnetic field. The local frequency response (i.e. the response of a given atomic nucleus) is referred to as the Larmor frequency (f_{Larmor}) and it is given by:

f_{Larmor}=γB₀ (1)

where γ is the gyromagnetic frequency ratio of the nucleus and B₀ is the modulus of the local static magnetic field. This local value may be affected by the chemical composition of the sample, thus making it possible to obtain crucial information about the nature, the composition, and the properties of the sample. The order of magnitude of the interactions that affect the NMR spectrum is parts per million (ppm). This implies that the ambient magnetic field must itself be more homogeneous than 1 ppm over the entire extent of the sample.

For this purpose, specially configured magnets are designed that produce a field that is extremely homogeneous, but rarely sufficiently homogeneous to enable spectroscopy to be performed without additional adjustments. This is particularly true when the sample itself often gives rise to distortions in the magnetic field because of its intrinsic magnetic susceptibility.

It is therefore necessary to have recourse to specific magnetic field correction coils, referred to as “shim coils”, that enable the final imperfections of the magnet to be compensated so as to obtain the necessary uniformity. Each “standard” NMR magnet, whether for liquids or for solids, is thus provided with a so-called “shim sheath”, which is no more than an assembly of magnetic field correction coils (shim coils) for passing currents that can be controlled independently. Adjusting current makes it possible to control the effect of each coil on the three-dimensional distribution of the field. The shim sheath is generally a cylindrical object of thickness that is moderate in order to occupy as little space as possible in the hole in the magnet. It is naturally coaxial with the hole in the magnet.

FIG. 7 is a diagram showing an example of an NMR spectrometer using magnetic field correction coils.

Such a spectrometer comprises an experimentation unit 1, an activation unit 2 comprising a set of electronic components, and a control unit 3 comprising a computer or a processor.

Inside the cylindrical hole of axis z in a magnet (not shown) for creating the main magnetic field, the experimentation unit 1 contains a sample 17 having radiofrequency coils 15 arranged thereabout, the radiofrequency coils themselves being surrounded by gradient coils 14 and by magnetic field correction coils 16 (shim coils).

The activation unit 2 comprises a unit 21 for powering the shim coils 16, a unit 22 for powering the gradient coils 14, and a unit 23 for transmitting RF signals to the RF coils 15 and for receiving RF signals transmitted by the RF coils 15.

The control unit 3 comprises a module 31 for determining values of signals to be given by the unit 21 for powering the shim coils 16, a module 32 for determining values of signals to be supplied by the unit 22 for powering the gradient coils 14, a module 33 for transmitting RF pulses to the unit 23 connected to the RF coils 15, and a module 34 for receiving radiofrequency NMR signals supplied by the unit 23 connected to the RF coils 15.

Obtaining a highly uniform magnetic field is a complex task. In order to simplify the problem, recourse is made to a major approximation. This consists in considering that, in a homogeneous field, variations in the modulus of the magnetic field are dominated by variation in the main component of the field. With superconducting magnets, the field is generally vertical in the reference frame of the laboratory. It has therefore become the practice to assume that the quantity B₀ is B_{z}, i.e. the vertical component of the magnetic field. It can then be shown that variations in B₀ are dominated by variations in B_{z}, providing these variations are small compared with the original value of the field.

This approximation thus makes it possible to take into consideration only one Cartesian component of the magnetic field. In a region empty of magnetic field sources, it can be shown that this component can be developed as a series of spherical harmonics. It is then possible in general manner, in the spherical coordinate system (r,θ,φ), and in the sphere inside the sources, to write the following:

$${B}_{z} = {Z}_{0} + {\sum }_{n = 1}^{∞} {r}^{n} [ {Z}_{n} {P}_{n} ( cos ϑ ) + {\sum }_{m = 1}^{n} ( {X}_{n}^{m} cos m ϕ + {Y}_{n}^{m} sin m ϕ ) {P}_{n}^{m} ( cos ϑ ) ] \qquad ( 2 )$$

Where (r,θ,φ) are the spherical coordinates of the point under consideration in a reference frame of axis Oz such that z=r cos θ with x=r sin θ cos φ and y=r sin θ sin φ. The Pₙ are the Legendre polynomials of degree n and the Pₙ^{m} are the associated Legendre polynomials of degree n and of order m. This development is unique and valid inside the largest magnetically empty ball of center O.

If the configuration of the field sources is axisymmetric on the axis Oz, the following simple form is obtained:

$${B}_{z} = {Z}_{0} + {\sum }_{n = 1}^{∞} {r}^{n} {Z}_{n} {P}_{n} ( cos ϑ ) \qquad ( 2.1 )$$

This is the form that is appropriate for a set of coaxial spirals of axis Oz. It can be reduced to a form that is even more simple for B_{z}(z) on the axis, i.e.:

$${B}_{z} = {Z}_{0} + {\sum }_{n = 1}^{∞} {Z}_{n} {z}^{n} \qquad ( 2.2 )$$

The terms Zₙ, Xₙ^{m}, and Yₙ^{m} are terms defined by the shape of the field sources.

The above-mentioned fundamental equation (2) provides the tools needed for solving the problem of homogeneity. Specifically, inside the inside sphere (i.e. the largest sphere that does not contain any field source), field variations due to a term Cₙ (i.e. Zₙ, Xₙ^{m}, or Yₙ^{m}) of degree n are in Cₙrⁿ.

However, it can be shown (by dimensional analysis or by direct calculation) that Cₙ varies with 1/r₀ⁿ. If rₛ is the greatest distance from a point of the sample to the origin, the contribution of the term Cₙ to the field varies with Cₙ(rₛ/r₀)ⁿ. For a sample of given size (rₛ<r₀), it thus suffices to compensate the terms of smaller degrees up to a degree n₀ that is sufficient to obtain the desired homogeneity in a given volume.

The design of the shim coils is thus based on this concept. Each of these coils is to process a particular term of the spherical harmonic development (SHD). Furthermore, the shape of the liquid sample used in NMR leads to greater weight being given to the “axial” terms (Zₙ) since the sample extends to a greater extent along the axis. This gives, “Z₁”, “Z₂”, “Z₃”, “Z₄”. “ZX”. “X”, “Y”, etc. coils, referenced using Cartesian coordinate notation for each term. It should be observed that the axial terms often extend to degree 4 or higher, while the non-axial terms are often limited to degree 3 or lower.

A simplified scheme for the state of the art in high-resolution NMR spectroscopy is shown in FIG. 11. The sample 17 can be seen placed along the axis z, and it can rotate about the axis at a frequency Cᵣ in order to average out the residual inhomogeneities of the magnetic field due to the non-axial terms (Xₙ^{m} and Yₙ^{m}). The shim coils are designed to perform corrections on the terms of the SHD relative to the laboratory coordinate system Oxyz.

Solid NMR has modified the standard configuration for liquid NMR by placing the sample of cylindrical shape along an axis that is inclined at the magic angle relative to the vertical (direction of the field). In contrast, the instrumentation has remained identical and the shim coils have remained in the laboratory reference frame. It is therefore necessary to change the reference frame in order to find the SHD associated with the reference frame inclined at the magic angle from the SHD associated with the laboratory reference frame. It is therefore necessary to have more non-axial terms in order to be able to compensate the field along this inclined axis. The procedure requires using as many as eight shim coils in order to be able to compensate the Z′₁, Z′₂, and Z′₃ terms in the reference frame of the sample (i.e. with an axis Oz′ at the magic angle relative to the Bz axis).

In order to make corrections at a degree higher than 4, it would be necessary to combine even more coils in the laboratory reference frame, which coils do not exist in commercial shim sheaths, and would be of very poor effectiveness.

### DEFINITION AND OBJECT OF THE INVENTION

The present invention seeks to remedy the above-mentioned drawbacks and to make it possible in simplified manner to make a device for correcting the homogeneity of a magnetic field for a magnetic resonance imaging or spectroscopy system.

The invention also seeks to provide a method of making such a device that is simplified while nevertheless making it possible to optimize the homogenization of the magnetic field created in the volume of interest.

In accordance with the invention, these objects are achieved by a method of correcting magnetic field in a magnetic resonance imaging system, said system comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, the correction being performed using correction coils arranged around said device for supporting the sample; the method being characterized in that it comprises the following steps:
defining an inclined coordinate system Ox′y′z′ attached to the sample, with a main axis Oz′ corresponding to said main dimension of the sample;
using a spherical harmonic development in said inclined coordinate system Ox′y′z′ attached to the sample to determine the shape of correction coils from a flux function F, each correction coil corresponding to a term of the spherical harmonic development;
for each correction coil, tracing iso-contours of the flux function F that are regularly spaced apart between the limits of the flux function F on a cylinder and including zero if there is a change of sign; and
from the iso-contours of the cylinder of each correction coil, forming winding elements in order to define said cylindrical correction coil positioned around the device for supporting the sample, the axis of said cylindrical coil coinciding with said direction Oz, the flux function F being such that a current distribution is obtained that minimizes the power dissipated for a value of a given axial term Z′n when the function F is a solution of a Poisson equation.

In an advantageous embodiment, said angle θ₀ other than zero corresponds to a so-called “magic” angle equal to arctan(√2)≈54.7°.

In a particular implementation, which is nevertheless simple and of high performance, first, second, and third correction coils are defined corresponding to the axial terms Z′₁, Z′₂, Z′₃ of the spherical harmonic development in said inclined coordinate system Ox′y′z′ attached to the sample.

Advantageously, each of the correction coils is powered with a current of adjustable value.

The invention also provides a device for magnetic field correction in a magnetic resonance imaging system, said system comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, said device for magnetic field correction comprising a set of correction coils positioned around the device for supporting the sample, the device being characterized in that each correction coil presents an axis coinciding with the direction Oz and comprises winding elements made from iso-contours of a flux function F that are regularly spaced apart between limits of the flux function F on a cylinder, the shape of the iso-contours being determined from a spherical harmonic development in an inclined coordinate system Ox′y′z′ attached to the sample with a main axis Oz′ corresponding to said main dimension of the sample, each correction coil corresponding to a term of the spherical harmonic development, the flux function F being such as to obtain a current distribution that minimizes the power dissipated for a value of a given axial term Z′n when the function F is a solution of a Poisson equation.

Advantageously, said angle θ₀ other than zero corresponds to a so-called “magic” angle equal to arctan(A√2)≈54.7°.

In a preferred embodiment, the set of correction coils comprises first, second, and third correction coils corresponding respectively to the axial terms Z′₁, Z′₂, Z′₃ of the spherical harmonic development in said inclined coordinate system Ox′y′z′ attached to the sample.

The invention also provides a magnetic resonance imaging system, comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, the device being characterized in that it includes a magnetic field correction device as defined above.

Said direction Oz may in particular be vertical or horizontal, depending on the intended application.

It should be observed that emphasizing the terms along the axis at the magic angle, as in the preferred implementations of the invention, is particularly pertinent when the rotation of the sample in an experiment rotating at the magic angle (“magic angle spinning” or (MAS)) reaches speeds of the order of 10 kilohertz (kHz) or more, which has the effect of canceling the influence of non-axial terms, even if they are large. Consequently, using the inclined reference frame for processing the terms of the SHD of the magnetic field component B_{z} is extremely important and effective.

In particular embodiments, the winding elements of the correction coils may, for example, comprise conductive tracks or wires on insulating supports.

### BRIEF DESCRIPTION OF THE DRAWINGS

Other characteristics and advantages of the invention appear from the following description of particular implementations of the invention, given as nonlimiting examples, and with reference to the accompanying drawings, in which:

FIG. 1 shows a diagrammatic view of the position of a sample for an NMR spectroscopy system to which it is possible to apply a magnetic field correction device of the invention;

FIG. 2 shows a diagrammatic axial section view of an example of a sample support device for tilting the sample and the support of a magnetic field correction device of the invention;

FIG. 3 shows, in a form developed in a plane, an example of iso-contours of the flux function for a correcting cylindrical coil generating a field profile dominated by the axial term Z′₁ of an SHD and for which the dissipated power for a given value of Z′₁ is a minimum;

FIG. 4 shows, in a form developed in a plane, an example of iso-contours of the flux function for a correcting cylindrical coil generating a field profile dominated by the axial term Z′₂ of an SHD and for which the dissipated power for a given value of Z′₂ is a minimum;

FIG. 5 shows, in a form developed in a plane, an example of iso-contours of the flux function for a correcting cylindrical coil generating a field profile dominated by the axial term Z′₃ of an SHD and for which the dissipated power for a given value of Z′₃ is a minimum;

FIG. 6 is a simplified block diagram of an example of a magnetic resonance spectroscopy or imaging system using a magnetic field correction device of the invention;

FIG. 7 shows a diagrammatic view of an example of a prior art magnetic resonance spectroscopy and imaging system;

FIG. 8 shows an example of a mask for fabricating an example of a coil for correcting the gradient Gₓ;

FIG. 9 shows an example of a mask for fabricating an example of a coil for correcting the gradient G_{y};

FIG. 10 shows an example of a mask for fabricating an example of a coil for correcting the gradient G_{z}; and

FIG. 11 shows a diagrammatic view of the position of a sample for a prior art NMR spectroscopy system.

### DETAILED DESCRIPTION OF PREFERRED EMBODIMENTS

According to the present invention, magnetic field correction coils or “shim” coils are proposed for taking account respectively of the axial terms Z′₁, Z′₂, and Z′₃, in preferred manner in a spherical harmonic development (SHD), the correction device including said coils being designed specifically for application to a magnetic resonance imaging system having a sample that is inclined relative to the direction of the main magnetic field by being oriented at an angle θ₀ that is preferably equal to the magic angle (54.7°).

These coils are always applied on a cylinder that is coaxial with the hole in the magnet creating the main field, and they may have the same dimensions as sheaths containing correction coils (referred to as “shim sheaths”) that are already in service, thereby enabling them to be used directly in existing installations. They serve to correct directly the terms of the SHD that are associated with the inclined reference frame. This greatly reduces the work of the operator who has to make corrections for irregularities in the main magnetic field created by the magnet.

Reference is made herein to axial terms Z′₁, Z′₂, and Z′₃ up to degree 3, since they are considered as being the most important, however the invention is naturally not limited in any way to this number, and the method of the invention can be used for calculating the characteristics of coils compensating other terms, of higher degree, or even terms that are not axial.

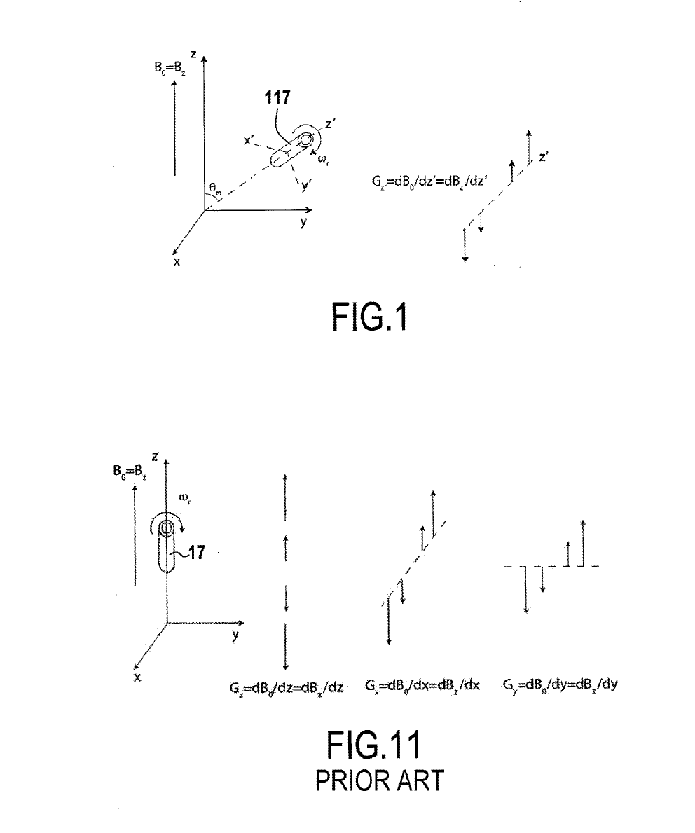

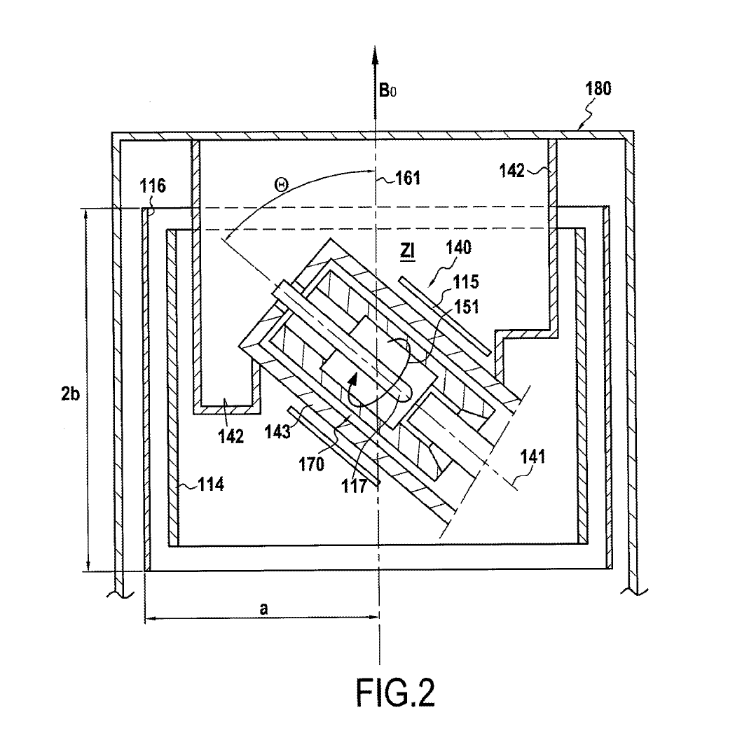

A simplified scheme for the application context of the invention is shown in FIG. 1. There can be seen the sample 117 placed along the axis z′, which is at the magic angle relative to the axis z of the magnetic field B₀. The sample 117 can turn about this axis z′ at a frequency ωᵣ in order to average out the anisotropic interactions and the residual inhomogeneities of the field. The correction coils 116 (FIG. 2) are designed to perform corrections on the terms of the SHD attached to the inclined coordinate system Ox′y′z′.

There follows a description of an example of calculating the characteristics of correction coils 116 of the invention.

The calculation begins by restricting the zone in which currents can exist to a cylindrical surface of radius a and of length 2b. In this context this is a static situation, and thus:

∇·\vec{j}=0, (3)

where \vec{j} is the current density.

Furthermore, once more because of the static conditions, the following applies at the limits:

\vec{j}·\vec{n}=0, (4)

where \vec{n} is the vector normal to the surface.

The current density is thus per unit area and is referred to below as k.

As a result of the presently imposed geometry, the following cylindrical coordinate system (ρ, φ, z) is adopted with its origin at the center of the cylinder. The cylinder is thus defined by two planes at positions z=b and z=−b and the axis of the cylinder passes through the origin, constituting its axis of symmetry. The axis of the cylinder is the axis of the NMR magnet, i.e. Oz in the laboratory reference frame.

The current distribution thus takes the general form:

\vec{k}(z,φ)=k_{φ}(z,φ)\vec{u_{φ}}+k_{z}(z,φ)\vec{u_{z}} (5)

It is then possible to apply Biot-Savart's law in order to find the general form of the distribution of the magnetic field induced by the currents. Attention is given here to the component Bz of the field, which is the dominant component in a standard NMR magnet. In order to identify the calculation point of the field, and using cylindrical coordinates in order to integrate over the surface carrying the currents, the following can be written, using Cartesian coordinates (x₀,y₀,z₀), where Oz is along the axis of the magnet:

$${B}_{z} ( {x}_{0} , {y}_{0} , {z}_{0} ) = \frac{{μ}_{0}}{4 π} {\int }_{- b}^{b} {\int }_{- π}^{π} \frac{( a - {x}_{0} cos φ - {y}_{0} sin φ ) {k}_{φ} ( z , φ )}{{( {a}^{2} + {x}_{0}^{2} + {y}_{0}^{2} + {( z - {z}_{0} )}^{2} - 2 a ( {x}_{0} cos φ + {y}_{0} sin φ ) )}^{\frac{3}{2}}} a d φ d z \qquad ( 6 )$$

Thereafter it is important to define appropriately the reference frame (Ox′y′z′) in which the SHD is expressed. With a rotating cylindrical sample 117, it is most advantageous to determine Oz′ as the axis of revolution of the sample. It is well-known that rapid rotation about the axis Oz′ serves to cancel the effect of non-axial terms in the NMR signal. This simplifies the task, which then needs only to adjust the axial terms. It is possible to think in terms of the sample's “own” reference frame.

The axial terms are none other than the n-derivatives along the axis Oz′ calculated at the origin. This gives:

$${Z}_{n}^{′} = \frac{1}{n !} {( \frac{{d}^{n} {B}_{α}}{d {z}^{′ n}} )}_{O} \qquad ( 7 )$$

The subscript alpha of the term B specifies the component of B along an axis of arbitrary orientation alpha. By way of example, alpha may be x, y, or z. In this specific application where the main field points along the axis z and truncates the transverse components, alpha may thus be z.

It is easy to express u_{z′} in the reference frame (x,y,z) as a function of its angle of inclination θ and assuming that this inclination is in the plane xOz. This gives:

u_{z′}=cos θu_{z0}+sin θuₓ_{₀}. (8)

It is thus possible to write the derivative along Oz′ as:

$$\frac{d f}{d {z}^{′}} = cos θ \frac{d f}{d {z}_{0}} + sin θ \frac{d f}{d {x}_{0}} \qquad ( 9 )$$

With the magic angle, this gives:

$$\begin{matrix} {Z}_{n}^{′} = \frac{{μ}_{0}}{4 π} {\int }_{- b}^{b} {\int }_{- π}^{π} {ζ}_{n} a d φ d z & ( 10 ) \\ {ζ}_{0} = \frac{a}{{( {a}^{2} + {z}^{2} )}^{\frac{3}{2}}} {k}_{φ} ( z , φ ) & ( 11 ) \\ {ζ}_{1} = \frac{\sqrt{3}}{3} \frac{( 3 az + \sqrt{2} ( 2 {a}^{2} - {z}^{2} ) cos φ )}{{( {a}^{2} + {z}^{2} )}^{\frac{5}{2}}} {k}_{φ} ( z , φ ) & ( 12 ) \\ {ζ}_{2} = \frac{1}{2} \frac{a ( 2 {z}^{2} - 3 {a}^{2} ) + 2 \sqrt{2} ( 4 {za}^{2} - {z}^{3} ) cos φ + 2 a ( 3 {a}^{2} - 2 {z}^{2} ) {cos}^{2} φ}{{( {a}^{2} + {z}^{2} )}^{\frac{7}{2}}} {k}_{φ} ( z , φ ) & ( 13 ) \\ {ζ}_{3} = \frac{\sqrt{3}}{3} ( - \frac{5 az ( 9 {a}^{2} - 2 {z}^{2} )}{{( {a}^{2} + {z}^{2} )}^{\frac{9}{2}}} + \frac{( 63 \sqrt{2} {a}^{2} {z}^{2} - 36 \sqrt{2} {a}^{4} - 6 \sqrt{2} {z}^{4} )}{{( {a}^{2} + {z}^{2} )}^{\frac{9}{2}}} cos φ + \frac{30 az ( 5 {a}^{2} - 2 {z}^{2} )}{{( {a}^{2} + {z}^{2} )}^{\frac{9}{2}}} {cos}^{2} φ + \frac{10 {a}^{2} ( 4 \sqrt{2} {a}^{2} - 3 \sqrt{2} {z}^{2} )}{{( {a}^{2} + {z}^{2} )}^{\frac{9}{2}}} {cos}^{3} φ ) k φ ( z , φ ) & ( 14 )\end{matrix}$$

As shown above, this gives:

\vec{∇}·\vec{k}=0, (15)

And

\vec{k}·\vec{n}=0, (16)

These equations imply that k is the rotation of a vector F such that:

\vec{k}=\vec{∇}×\vec{F} (17)

\vec{F}=F(z,φ)\vec{u}_{z} (18)

F is referred to as the flux function. It can then be shown that the current distribution minimizing dissipated power can be obtained for a value of a given axial term Z′ₙ when the function F is a solution of a Poisson equation. The second member of this equation is given by the constraints set on the field profile, i.e. the relative values desired for the axial terms Z′ₙ (including canceling certain terms, if necessary).

The flux function F thus minimizes a target function, while complying with the constraints. The target function P′ may be considered as being proportional to the power P dissipated by the Joule effect.

The following relationships thus apply:

$$P = \frac{a}{σ e} {P}^{′} \qquad ( 19 )$$

P′∫∫_{S}(k_{φ}²+k_{z}²)dφdz (20)

where e is the thickness of the thin conductive layer of electrical conductivity σ.

This expression needs to be transformed so that it makes use only of the flux function, and the same must be done for the expressions for the constraints. These are the expressions of coefficients of the SHD or of coefficients Zₙ′, that are to take fixed values or that are not to exceed a given limit in absolute value. Since they are relative to the component B_{z} of the field produced, they do not depend on k_{z} and they depend linearly on k_{φ} with the following generic form:

Kᵢ′=∫∫_{S}k_{φ}fᵢ(φ,z)dφdz (21)

Once the flux function F has been found, it suffices to trace on the cylinder iso-contours of this function F that are spaced apart in a regular manner between the limits of F (including zero if there is a change of sign), in order to obtain either the positions of loops described by a conductor wire or by a conductive track, or else the positions of cutouts in a conductive plate (e.g. of the copper sheet type).

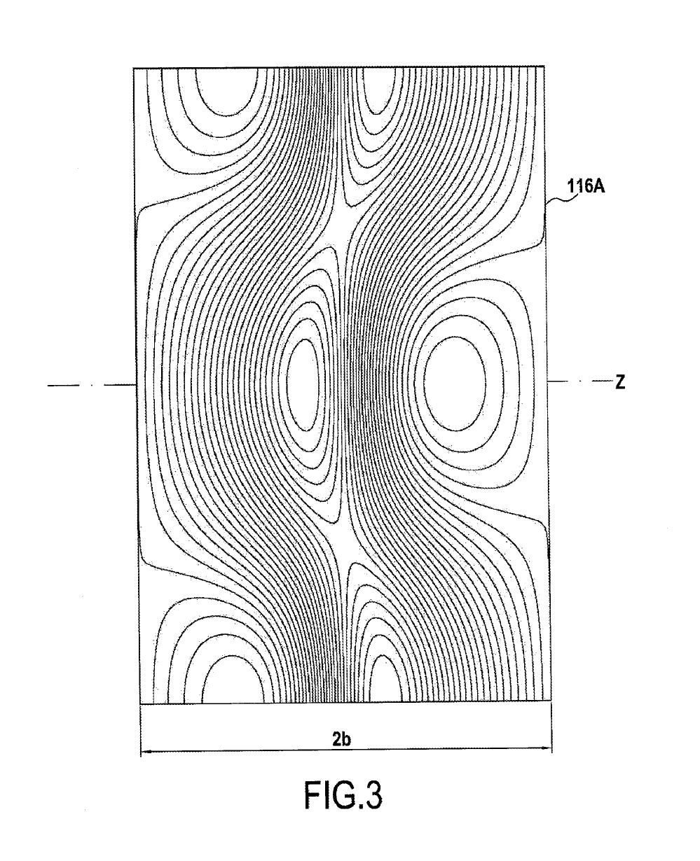

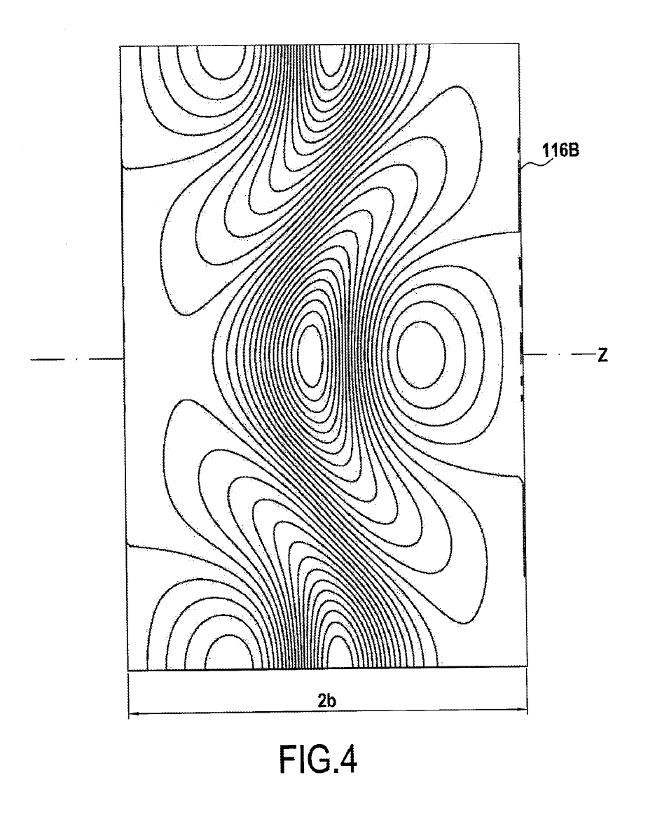

FIGS. 3 and 5 show examples of cylindrical coils 116A, 116B, 116C, each generating a magnetic field profile dominated by one axial term Z′ₙ.

For each figure, the abscissa axis represents the direction parallel to the axis z of the cylinder and the ordinate axis represents angular position on the cylinder. It thus suffices to wrap the figure around a cylinder of appropriate radius in order to obtain the coil. The diagram is to scale and only the proportion between the radius a of the cylinder and its length 2b needs to be kept constant in order to conserve the calculated properties (apart from the magnitude of the term generated per power unit, which decreases when the radius a increases).

FIG. 3 shows an example of a cylindrical coil 116A generating a field profile dominated by Z′₁ and having minimum dissipated power for a given value of Z′₁.

FIG. 4 shows an example of a cylindrical coil 116B generating a field profile dominated by Z′₂ and having minimum dissipated power for a given value of Z′₂.

FIG. 5 shows an example of a cylindrical coil 116C generating a field profile dominated by Z′₃ and having minimum dissipated power for a given value of Z′₃.

In order to make cylindrical correction coils, it is possible, by way of example, to use insulated copper wire of constant section that may be circular or rectangular and that is glued to the contours as a function of flux. As can be seen in the examples of FIGS. 3 to 5, there exists a set of various iso-contours nested in one another, like contour lines on a map. It is appropriate to go from one iso-contour to a neighboring iso-contour by opening the loop and using a straight segment of wire in a location that is selected to avoid contributing to the main field of the correction device. Thus, the closed loops of the conductor wires superposed on the iso-contours are connected in series, and preferably the connecting segments are arranged parallel to the axis Oz so that they do not create any additional field in this direction.

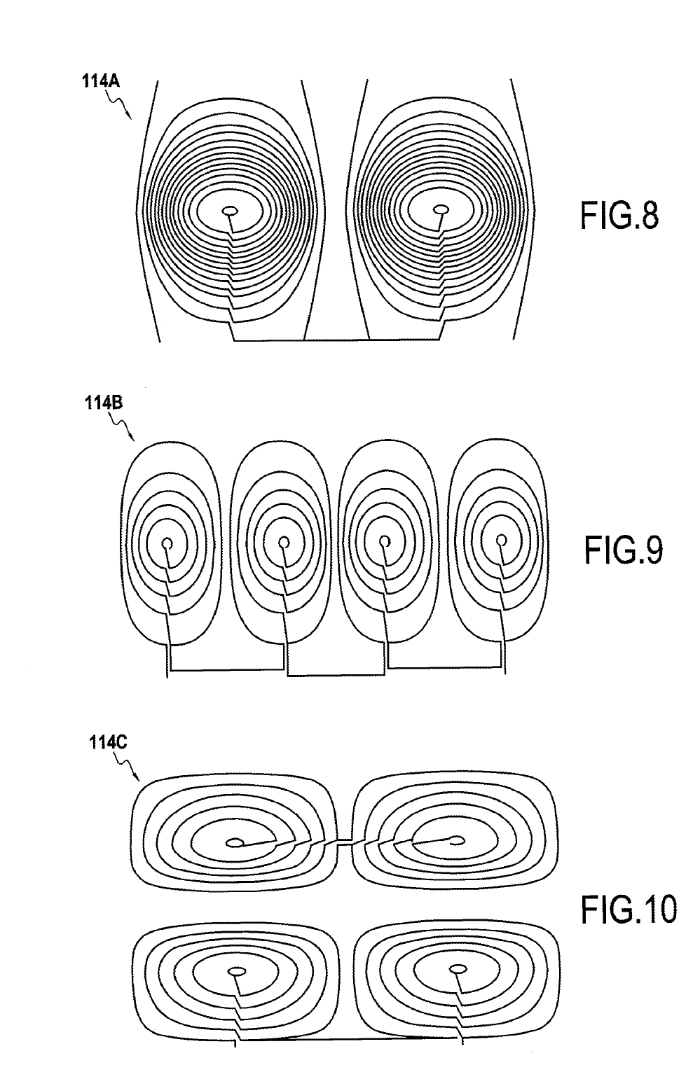

The invention also makes it possible to make coils for correcting the gradients Gₓ, G_{y}, and G_{z} from the iso-contours of a flux function, e.g. as shown in FIGS. 8 to 10, which relate respectively to a coil for correcting the gradient Gₓ, to a coil for correcting the gradient G_{y}, and to a coil for correcting the gradient G_{z}. FIGS. 8 and 10 show respective masks 114A, 114B, and 114C for making conductive tracks on a face of a printed circuit so as to constitute winding elements for the gradients Gₓ, G_{y}, and G_{z}. These masks show in particular passages for passing current between the tracks corresponding to neighboring iso-contours, so as to define series connections. It is possible to use a mask on each of the faces of a printed circuit so as to double the effectiveness of the coil. Current passes from one face to the other through vias placed at the centers of the center contours. The gradient-correcting coils serve to increase the linearity of field variation in a fixed direction Oz, in a region of interest, in the same manner as correction coils such as the correction coils 116A, 116B, and 116C seek to make the magnetic field as invariable as possible in the direction Oz in the region of interest.

FIG. 2 shows an example NMR spectroscopy device comprising a housing 180 inserted in the tunnel of a magnet (not shown) that creates a homogeneous magnetic field B₀ in a zone of interest ZI, the magnetic field having an axial component oriented along an axis z 161 of the laboratory.

A measurement device 140 has a casing 143 connected by support elements 142 to the housing 180. The casing 143 contains a sample 117 of elongate shape oriented along an axis z′ 141 forming an angle θ relative to the axis z 161 of the main magnetic field B₀. The sample 117 may be driven in rotation about its axis z′ (rotary movement 151) by a rotary drive device 170.

FIG. 2 shows diagrammatically: RF coils 115 (which surround the casing 143 and are coaxial with the sample 117 oriented along the axis z′ 141); gradient coils 114 (having as their axis the axis z 161 of the laboratory); and cylindrical magnetic field correction coils 116 (of radius a and of length 2b) of characteristics that are determined in the above-described manner while taking into consideration a reference frame Ox′y′z′ associated with the sample 117 and having as their axis the axis z 161 of the laboratory.

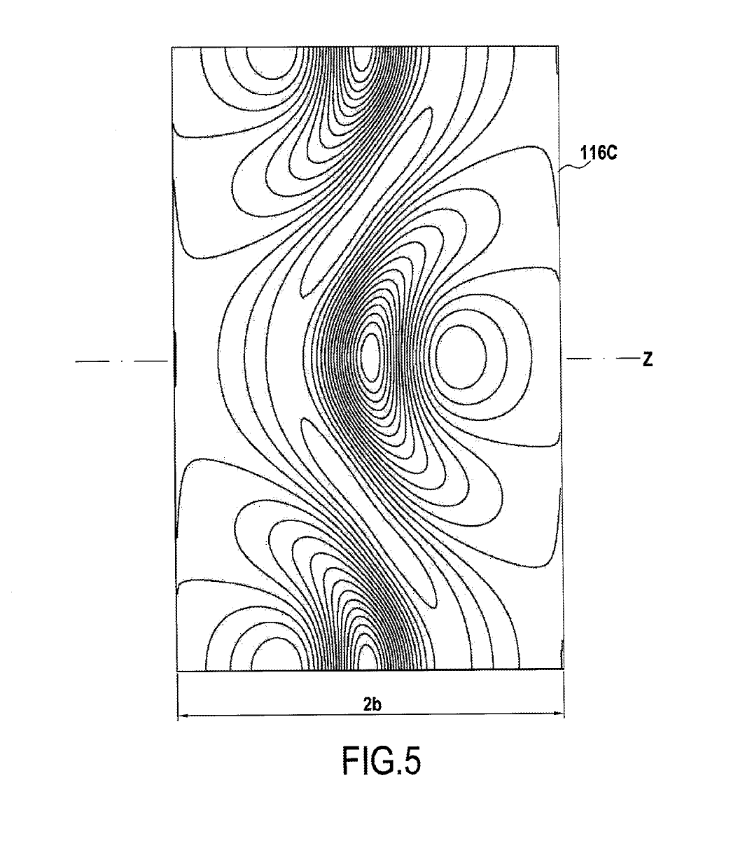

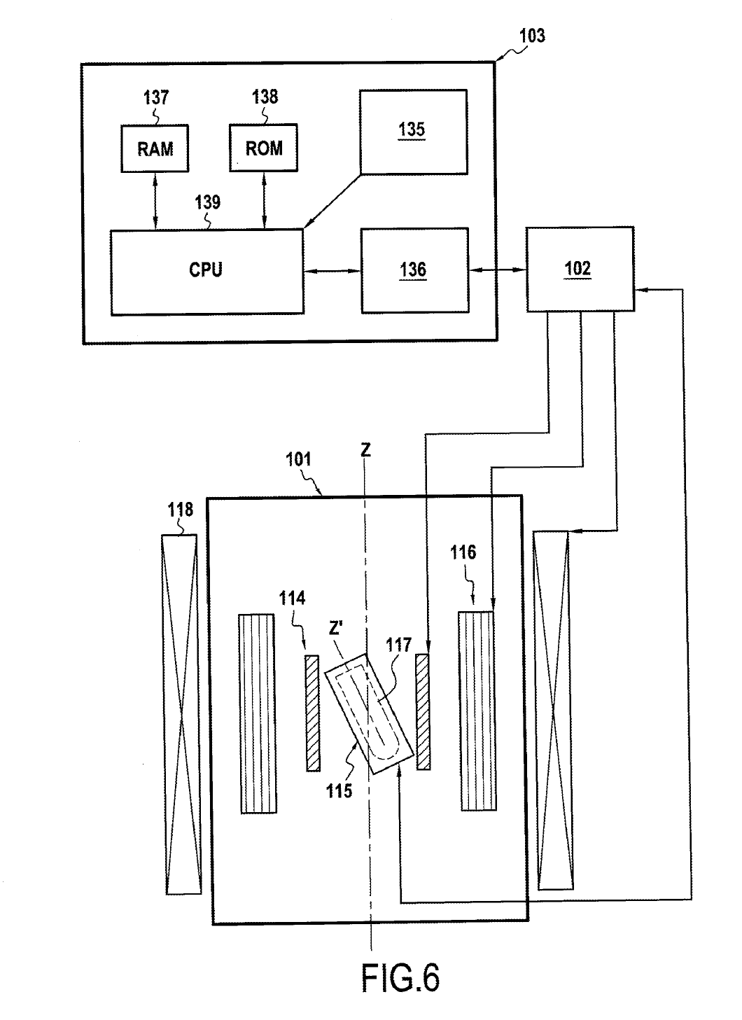

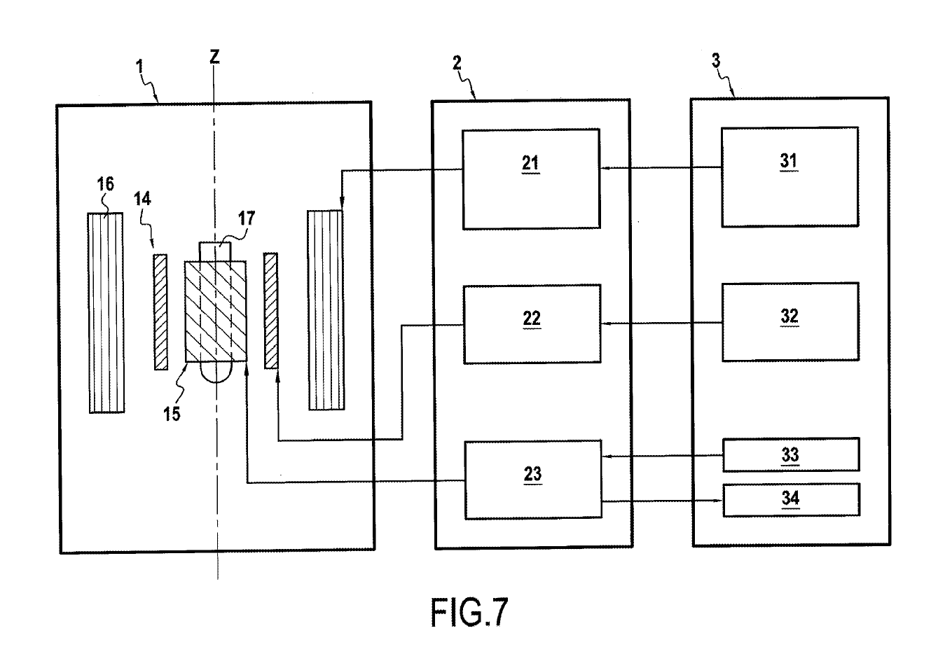

FIG. 6 shows diagrammatically the overall magnetic resonance spectroscopy and imaging system to which the invention is applicable.

Inside the cylindrical hole of a magnet 118 for creating a main magnetic field having a component B_{z} oriented along an axis z, an experimentation unit 101 comprises, going from the outside towards the inside: magnetic field correction coils 116 coaxial about the axis z; gradient coils 114 (likewise coaxial about the axis z); and RF coils 115 placed as close as possible to the sample 117.

The sample 117 of shape that is elongate along an axis z′ is itself inclined at a predetermined angle, e.g. the magic angle, relative to the axis z, as are the RF coils 115 that surround the sample 117.

An activation unit 102 powers the various coils of the experimentation unit 101 and also receives in return the modulated RF signals from the RF coils 115.

A control unit 103 (which may be constituted by a computer) comprises a module 136 for communication between a central processor unit 139 and the activation unit 102, random access memory (RAM) units 137, read only memory (ROM) units 138, and a user interface 135. The values of the various signals for supplying by the activation unit 102 are determined by the control unit 103.

In summary, the space available for a magnetic field source having given characteristics is often very limited in certain directions and leads to making use of current distributions on an imposed geometrical surface. In practice, these surface distributions are made in approximate manner, either by placing filamentary conductors on the surface, or by making appropriate cutouts in thin conductive sheets, or else by using printed circuit techniques.

For example, magnetic resonance imaging (MRI) machines need to be provided with gradient sources for the main component of the magnetic field in three directions Gₓ, G_{y}, and G_{z}, that are as homogeneous as possible. In most machines, the gradient sources need to be placed inside the empty circular cylinder of the main magnet and to occupy a minimum amount of space therein, which confines them to an annular cylindrical space of small thickness. They can be made by means of copper wire windings of appropriate shape (in helices for Gₓ and in saddle shapes for Gₓ or G_{y}) or also by means of thin tracks (or track portions) made of copper and having cutouts formed therein in order to create current flow channels.

In these machines, and also in all magnets for producing a magnetic field that is very homogeneous in a given region, it is necessary to provide devices for correcting imperfections of the field resulting from the sources (windings passing currents or magnetized materials) being made imperfectly or from disturbances that may equally well be external to the magnet or internal (the sample and its supports). If the devices, referred to as “shims”, are made using sheaths, then the search for minimum size also leads to using surface distributions that generate a magnetic field in which the component along the direction Oz of the main field presents a given profile in the region of interest.

The invention, which makes it possible to determine the surface current densities carried by a circular cylinder generating a given profile of the component of the magnetic field along the axis Oz of the cylinder, can be used in the design of various types of corrector systems or field gradient generators.

1. A method of correcting magnetic field in a magnetic resonance imaging system, said system comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, the correction being performed using correction coils arranged around said device for supporting the sample; the method comprising the following steps:
defining an inclined coordinate system Ox′y′z′ attached to the sample, with a main axis Oz′ corresponding to said main dimension of the sample;
using a spherical harmonic development in said inclined coordinate system Ox′y′z′ attached to the sample to determine the shape of correction coils from a flux function F, each correction coil corresponding to a term of the spherical harmonic development;
for each correction coil, tracing iso-contours of the flux function F that are regularly spaced apart between the limits of the flux function F on a cylinder and including zero if there is a change of sign; and
from the iso-contours of the cylinder of each correction coil, forming winding elements in order to define said cylindrical correction coil positioned around the device for supporting the sample, the axis of said cylindrical coil coinciding with said direction Oz, the flux function F being such that a current distribution is obtained that minimizes the power dissipated for a value of a given axial term Z′ₙ when the function F is a solution of a Poisson equation.

2. The method according to claim 1, wherein said angle θ₀ other than zero corresponds to a so-called “magic” angle equal to arctan(√2)≈54.7°.

3. The method according to claim 1, wherein first, second, and third correction coils are defined corresponding to the axial terms Z′₁, Z′₂, Z′₃ of the spherical harmonic development in said inclined coordinate system Ox′y′z′ attached to the sample.

4. The method according to claim 1, wherein each of the correction coils is powered with a current of adjustable value.

5. A device for magnetic field correction in a magnetic resonance imaging system, said system comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, said device for magnetic field correction comprising a set of correction coils positioned around the device for supporting the sample, wherein each correction coil presents an axis coinciding with the direction Oz and comprises winding elements made from iso-contours of a flux function F that are regularly spaced apart between limits of the flux function F on a cylinder, the shape of the iso-contours being determined from a spherical harmonic development in an inclined coordinate system Ox′y′z′ attached to the sample with a main axis Oz′ corresponding to said main dimension of the sample, each correction coil corresponding to a term of the spherical harmonic development, the flux function F being such as to obtain a current distribution that minimizes the power dissipated for a value of a given axial term Z′ₙ when the function F is a solution of a Poisson equation.

6. The device according to claim 5, wherein said angle θ₀ other than zero corresponds to a so-called “magic” angle equal to arctan(√2)≈54.7°.

7. The device according to claim 5, wherein the set of correction coils comprises first, second, and third correction coils corresponding respectively to the axial terms Z′₁, Z′₂, Z′₃ of the spherical harmonic development in said inclined coordinate system Ox′y′z′ attached to the sample.

8. The device according to claim 5, wherein the winding elements of the correction coils comprise conductive tracks or wires on an insulating support.

9. A magnetic resonance imaging system, comprising a device for creating a main magnetic field along a direction Oz in a zone of interest ZI, a device for supporting a sample with a main dimension of the sample being oriented at an angle θ₀ other than zero relative to said direction Oz, gradient coils, and radiofrequency coils, and a magnetic field correction device according to claim 5.

10. The system according to claim 9, wherein said direction Oz is vertical.

11. The system according to claim 9, wherein said direction Oz is horizontal.
